(19) United States
(12) Patent Application Publication
(10) Pub. No.: US 2013/0270508 A1
(43) Pub. Date: Oct. 17, 2013

(54) Non-Volatile Memory Device and Method of Forming the Same

(71) Applicant: AGENCY FOR SCIENCE, TECHNOLOGY AND RESEARCH, Singapore (SG)

(72) Inventors: Xiang LI, Singapore (SG); Navab Singh, Singapore (SG); Zhixian Chen, Singapore (SG); Xinpeng Wang, Singapore (SG); Guo-Qiang Patrick Lo, Singapore (SG)

(73) Assignee: Agency for Science, Technology and Research, Singapore (SG)

(21) Appl. No.: 13/860,870

(22) Filed: Apr. 11, 2013

(30) Foreign Application Priority Data
Apr. 11, 2012 (SG) SG201202613-4

(51) Int. Cl. H01L 45/00

(52) U.S. Cl. CPC H01L 45/1206; H01L 45/16; Y10S 977/762; Y10S 977/84; Y10S 977/938; B82Y 10/00
USPC 257/4; 438/382; 977/762; 977/840; 977/938

(57) ABSTRACT

According to embodiments of the present invention, a non-volatile memory device is provided. The non-volatile memory device includes a nanowire transistor including a nanowire channel, and a resistive memory cell arranged adjacent to the nanowire transistor and in alignment with a longitudinal axis of the nanowire channel. According to further embodiments of the present invention, a method of forming a non-volatile memory device is also provided.

### CROSS-REFERENCE TO RELATED APPLICATION

This application claims the benefit of priority of Singapore patent application No. 201202613-4, filed Apr. 11, 2012, the contents of which are incorporated herein by reference for all purposes.

### TECHNICAL FIELD

Various embodiments relate to a non-volatile memory device and a method of forming the non-volatile memory device.

### BACKGROUND

Conventional non-volatile memory (NVM) devices include floating gate FLASH and discrete charge trap-based devices, e.g. Silicon-Oxide-Nitride-Oxide-Silicon (SONOS), TaN—Al₂O₃—Si₃N₄—SiO₂—Si (TANOS) and nanocrystal (NC) memory cells. SONOS or floating gate NVM are three terminal devices, which face endurance and retention problem while scaling to <20 nm. Their program/erase (P/E) voltage is also high. Emerging non-volatile memory include resistive random-access memory (RRAM), phase-change random access memory (PCRAM) and magnetoresistive random access memory (MRAM), which may be based on technology nodes of 32 nm, 22 nm or beyond. However, phase change memory may have a high program/erase (P/E) current and thermal cross talk issues.

Resistive random-access memory (RRAM) has been studied extensively in recent years due to its potential being the solution to the scaling issues in current charge-trapping based non-volatile memory (NVM). Superior data retention, high speed program/erase (P/E) and low operating voltages make it suitable particularly for embedded NVM applications using standard CMOS back end of line (BEOL) process. Therefore, RRAM may offer ultra high density, high speed, low power, nonvolatile memory scalable to sub-10 nm technology node.

FIG. 1A shows a schematic cross sectional view of a conventional resistive random-access memory (RRAM) cell 100. The RRAM cell 100 includes a top electrode (TE) 102, a bottom electrode (BE) 106, and a switching material 104 sandwiched in between. When a plurality of RRAM cells, e.g. 100, are arranged in a memory array where a respective RRAM cell may be accessed or selected by a respective bit line and a respective word line, when a particular RRAM cell is accessed, there may be an issue relating to sneak path where a leakage current may flow through a neighbouring RRAM cell, which may cause cross-talk interference and/or read error effect. One approach, as shown in FIG. 1B, may be to integrate a select device 108 with each RRAM cell having the switching material 104 for a memory cell 120. However, integrating a select device with each RRAM cell may incur issues such as area penalty and process complexity.

FIG. 1C shows a schematic cross sectional view of a conventional memory cell 140 including a RRAM cell having a storage dielectric 104 with an access transistor 108. The memory cell 140 has a 1T1R configuration. The access transistor 108 may have a gate terminal (G) coupled to a word line (WL) 142, a first source/drain terminal (S/D₁) coupled to a bit line (BL) 144 and a second source/drain terminal (S/D₂) coupled to the storage dielectric 104. The storage dielectric 104 may also be coupled to a source line (VSL) 146. The RRAM cell area may be 4F² (F refers to the minimum feature size) while the select device (i.e. access transistor 108) area may be 8F². Such a memory cell 140 may offer a universal solution, as using a transistor as the selection device may accommodate both unipolar and bipolar switchings, whereas a diode as the selection device can be integrated with only unipolar RRAM. Hence, a 1T1R may have wider applications than a 1D1R.

FIG. 1D shows a schematic cross sectional view of a conventional memory cell 160 including an RRAM cell having a storage dielectric 104 with an access diode 108. The memory cell 160 has a 1D1R configuration. The storage dielectric 104 may be coupled to a word line (WL) 142 and to the cathode (“−”) terminal of the access diode 108. The anode (“+”) terminal of the access diode 108 may be coupled to a bit line (BL) 144. Each of the RRAM cell area and the select device (i.e. access diode 108) area may be 4F². Due to the presence of the access diode 108, the memory cell 160 has a unidirectional or unipolar mode of operation (unidirectional current flow).

A RRAM cell integrated with a 3-dimensional (3D) vertical bipolar junction transistor (BJT) has been demonstrated to have 4F² footprint. It uses a transistor (other than diode) as the select device with 4F² density. However, BJT has a higher leakage current and it may complicate the process flow if it is to be implemented along with CMOS logic.

In addition, for conventional memory cells or devices, non-CMOS material, e.g. Pt may be used, therefore incompatible with CMOS processes. Furthermore, there may be issues with complex processes and integration, and high program/erase (P/E) current, for example >100 μA.

### SUMMARY

According to an embodiment, a non-volatile memory device is provided. The non-volatile memory device may include a nanowire transistor including a nanowire channel, and a resistive memory cell arranged adjacent to the nanowire transistor and in alignment with a longitudinal axis of the nanowire channel.

According to an embodiment, a method of forming a non-volatile memory device is provided. The method may include forming a nanowire transistor including a nanowire channel, and forming a resistive memory cell adjacent to the nanowire transistor and in alignment with a longitudinal axis of the nanowire channel.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross sectional view of a conventional resistive random-access memory (RRAM) cell.

FIG. 1B shows a schematic cross sectional view of a conventional memory cell including an RRAM cell with a select device.

FIG. 1C shows a schematic cross sectional view of a conventional memory cell including an RRAM cell with an access transistor.

FIG. 1D shows a schematic cross sectional view of a conventional memory cell including an RRAM cell with an access diode.

FIG. 2A shows a schematic block diagram of a non-volatile memory device, according to various embodiments.

FIG. 2B shows a flow chart illustrating a method of forming a non-volatile memory device, according to various embodiments.

FIG. 3A shows a schematic perspective view of a non-volatile memory device, according to various embodiments.

FIG. 3B shows a schematic perspective view of a non-volatile memory device, according to various embodiments.

FIG. 3C shows a schematic perspective view of a non-volatile memory arrangement, according to various embodiments.

FIGS. 4A to 4C respectively show schematic cross sectional views of non-volatile memory devices, according to various embodiments.

FIGS. 5A to 5J show, as cross-sectional views, various processing stages of a method of forming a non-volatile memory device, according to various embodiments.

FIGS. 6A to 6H show scanning electron microscopy (SEM) micrographs of a 4×4 array of non-volatile memory devices in various process steps, according to various embodiments. All scale bars are 500 nm unless otherwise stated.

FIG. 7A shows a transmission electron microscopy (TEM) micrograph of a fabricated 1T1R memory cell while FIG. 7B shows a high resolution image of the fabricated 1T1R memory cell, according to various embodiments.

FIG. 8A shows a plot of the transistor output characteristics of a control wafer without a memory cell and a 1T1R wafer with a RRAM cell in low resistance state (LRS), according to various embodiments.

FIG. 8B shows a plot illustrating memory cell operations under unipolar and bipolar modes at V_{WL}=V_{SL}=0V, according to various embodiments.

FIG. 9A shows a plot of unipolar mode switching for an n⁺ doped nanowire (without FET) and 1T1R cells of different nanowire diameters, according to various embodiments

FIG. 9B shows a plot of ultralow current bipolar mode switching, according to various embodiments.

FIGS. 10A and 10B respectively show plots of DC endurance cycles and room temperature (RT) retention for unipolar mode switching.

FIGS. 11A and 11B respectively show plots of DC endurance cycles and room temperature (RT) retention for ultralow current bipolar mode switching.

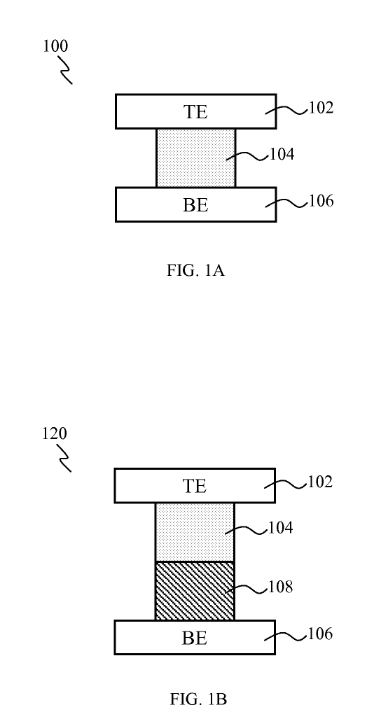

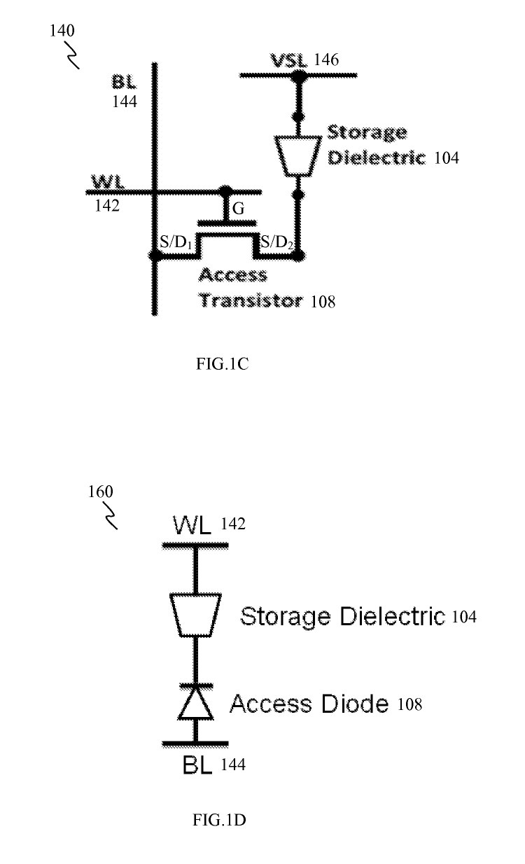

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element includes a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may relate to device architectures including one or more RRAM cells and selection devices, e.g. transistor, for example relating to an integration of resistive switching random access memory with vertical gate-all-around (GAA) semiconductor nanowire select transistors and a method of producing the same.

Various embodiments may provide non-volatile memory (NVM) devices and/or arrangements for high density non-volatile memory (NVM) applications and methods of fabricating the non-volatile memory devices and/or arrangements. The non-volatile memory (NVM) device may include a resistive memory cell, for example in the form of resistive random access memory (RRAM) cell. In various embodiments, a RRAM cell may have a metal-insulator-metal (M-I-M) configuration.

Various embodiments may provide a RRAM integration scheme, which integrates RRAM cells on or towards the top of vertical nanowires, for example a RRAM cell may be stacked on or towards the top of a vertical nanowire. The vertical nanowires may form a nanowire channel or a conduction channel for a nanowire transistor.

Various embodiments may provide a non-volatile memory device having a 1T (transistor)+1R (resistive memory cell; RRAM) architecture. The selector (1T) for each resistive memory cell (1R) may enable proper switching of the intended resistive memory cell to minimize or eliminate the cross-talk interference from neighbouring resistive memory cells in an array structure, and/or minimise or prevent read error effect. The 1T may be a nanowire-based transistor.

Various embodiments may provide vertical 1T1R non-volatile memory (NVM) cells and a method of fabricating the same. Various embodiments of the non-volatile memory devices may provide a 1T1R configuration with 4F² footprint. The non-volatile memory devices of various embodiments may exhibit ultralow power program/erase (P/E). The non-volatile memory devices of various embodiments may include a self-aligned memory cell (RRAM cell) using silicon (Si) as a bottom electrode and only one additional masking layer. The RRAM cell area may be tunable by controlling the spacer over-etch and forming the cell on the nanowire sidewall without occupying planar area.

Various embodiments may provide a direct way to realize the 4F² density for a non-volatile memory device or cell by integrating the memory cell on a vertically metal oxide semiconductor field-effect transistor (MOSFET). Various embodiments may provide 4F² cell with MOS transistor as a select device. Various embodiments may provide integration of 4F² RRAM cell on top of 4F² vertical transistor (e.g. vertical nanowire transistor), which may offer a universal solution enabling both unipolar and bipolar switchings, with zero or minimal area penalty.

Various embodiments may provide a 1T1R integration of RRAM cell with vertical nanowire CMOS to achieve 4F² footprint for large scale storage usage. A full CMOS compatible process flow, with only one additional mask layer, may be used to realize this self-aligned 1T1R structure. Excellent device characteristics and current scalability may be obtained with this structure. Ultra-low current switching may be achieved for low power applications in portable electronics devices.

In various embodiments, a non-volatile memory device having a 1T1R structure may be provided, having a two-terminal resistive memory cell (e.g. RRAM cell) and a three-terminal vertical GAA nanowire transistor as the selection device of the resistive memory cell. The resistive memory cell may be electrically and/or mechanically coupled with the nanowire transistor. A standard vertical nanowire transistor process may be used to form the select transistor for the memory cell and array. The nanowire transistor may be junction based enhancement mode or junction-less depletion mode field effect transistor or a tunneling field effect transistor.

In various embodiments of the 1T1R memory device, the nanowire top or top end portion of the nanowire transistor may be implanted with dopants or in other words, doped, and the implanted nanowire top may be directly used as the bottom electrode (BE) of the RRAM cell. This may mean that the RRAM cell may be arranged adjacent or towards the implanted nanowire top. The RRAM cell may be self-aligned with a source/drain terminal or region of the nanowire transistor.

In various embodiments, the size of the RRAM cell may be determined by the bottom electrode (e.g. Si bottom electrode in embodiments where the nanowire includes silicon (Si)), which may include the top and one or more sidewalls of the nanowire. The curvature in the RRAM cell, which for example may be cylindrical, may provide field enhancement and thus a reduction in forming voltage. The forming voltage refers to the voltage at which a fresh device is initially SET, e.g. where the conduction path is “formed”. The RRAM cell size may be precisely tuned by controlling the spacer over-etch, for example during fabrication.

In various embodiments, the top or top end portion of the nanowire, e.g. Si nanowire, may be silicided to form nickel silicide (NiSi), titanium silicide (TiSi₂), cobalt silicide (CoSi₂) or other metal silicides to serve as the bottom electrode of the RRAM cell. Alternatively, other metal electrode may be deposited and etched (in a self-aligned spacer form) to serve as the bottom electrode of the RRAM cell.

A thin dielectric layer, e.g. of hafnium oxide (HfO₂), may be deposited onto the bottom electrode to serve as the switching dielectric or material. In addition or alternatively, other dielectric materials such as titanium oxide (TiO₂), aluminium oxide (Al₂O₃), tantalum oxide (Ta₂O₅) or multilayer of dielectric materials may be deposited to serve as the switching dielectrics. In should be appreciated that the dielectric layer may be of or may include other transition metal oxide(s). In various embodiments, the dielectric layer may be a resistive layer including a resistive changing material.

A metal layer including but not limited to platinum (Pt), nickel (Ni), aluminum (Al), titanium nitride (TiN), tantalum nitride (TaN), hafnium nitride (HfN), or aluminum nitride (AlN) or any combination thereof may be deposited and patterned to serve as the top electrode (TE) of the RRAM cell. In various embodiments, the RRAM cell may include the bottom electrode (BE), the dielectric layer and the top electrode (TE).

In various embodiments, any one or each RRAM cell may have two modes of operation or switching modes, which may include unipolar and bipolar modes.

In various embodiments, any one or each RRAM cell may have low power operations: for example SET 10 μA/30 μW and RESET 20 μA/30 μW for unipolar mode, SET 20 nA/85 nW and RESET 0.2 nA/0.7 nW for bipolar mode.

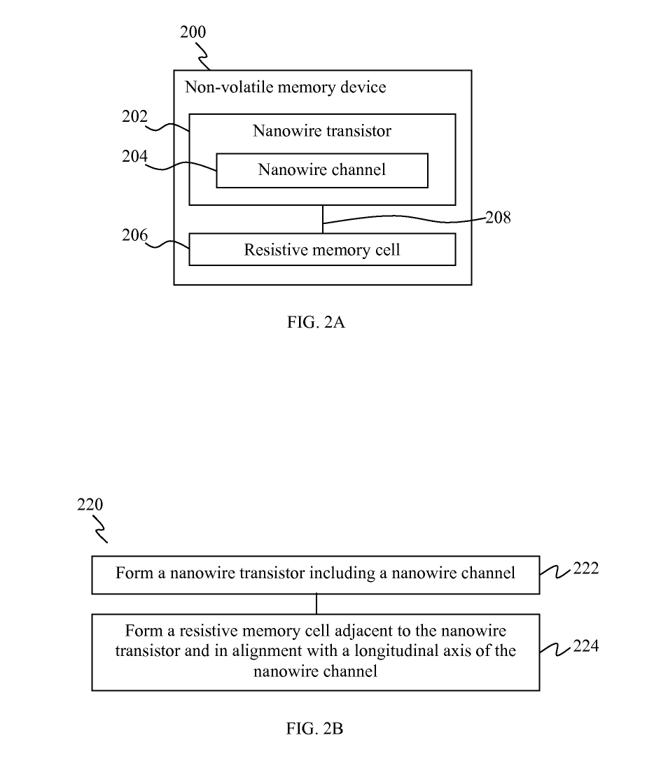

FIG. 2A shows a schematic block diagram of a non-volatile memory device 200, according to various embodiments. The non-volatile memory device 200 includes a nanowire transistor 202 including a nanowire channel 204, and a resistive memory cell 206 arranged adjacent to the nanowire transistor 202 and in alignment with a longitudinal axis of the nanowire channel 204. The line represented as 208 is illustrated to show the relationship among the nanowire transistor 202, the nanowire channel 204 and the resistive memory cell 206, which may include electrical coupling and/or mechanical coupling.

In other words, the non-volatile memory device 200 may include a nanowire-based transistor 202 having a nanowire channel 204. The non-volatile memory device 200 may further include a resistive memory cell (e.g. RRAM cell) 206 which may be arranged adjacent to the nanowire transistor 202. The resistive memory cell 206 may be aligned with a longitudinal axis of the nanowire channel 204, for example arranged along the longitudinal axis of the nanowire channel 204.

In the context of various embodiments, the term “nanowire channel” may mean a nanostructure channel extending, for example in a longitudinal direction, with dimensions in the order of nanometers. In the context of various embodiments, the nanowire channel 204 may serve as a conducting channel.

In the context of various embodiments, the nanowire channel 204 may be in the form of a nanowire, a nanorod, a nanotube, a nanopillar, a nanocolumn and the likes. In the context of various embodiments, the nanowire channel 204 may include but not limited to silicon (Si), germanium (Ge) or III-V semiconductors including one or more group III elements (e.g. aluminum (Al), gallium (Ga) or indium (In)) and one or more group V elements (e.g. nitrogen (N), arsenic (As) or antimony (Sb)).

In the context of various embodiments, the nanowire channel 204 may include silicon. As non-limiting examples, the nanowire channel 204 may include a silicon nanowire, a polysilicon nanowire (i.e. polycrystalline silicon nanowire) and a silicon-germanium nanowire. However, it should be appreciated that any silicon-based nanowires may be provided.

In the context of various embodiments, the nanowire channel 204 may have a diameter or a cross sectional dimension of between about 10 nm and about 200 nm, for example between about 10 nm and about 100 nm, between about 10 nm and about 50 nm or between about 50 nm and about 200 nm. The term “cross sectional dimension” may mean a dimension of a cross section of the nanowire channel 204 defined along a transverse axis (perpendicular to the longitudinal axis) of the nanowire channel 204.

In the context of various embodiments, the nanowire channel 204 may have a length or height of between about 100 nm and about 2 μm, for example between about 100 nm and about 1 μm, between about 100 nm and about 500 nm, or between about 500 nm and about 2 μm.

In the context of various embodiments, the length of the nanowire channel 204 may be at least 3 times that of the diameter of the nanowire channel 204 so as to avoid or minimise any short channel effect and/or to maintain good gate control. In various embodiments, the height of the nanowire channel 204, and hence the channel length, may be limited in the vertical platform. In various embodiments, as the length of the nanowire channel 204 increases, the diameter of the nanowire channel 204 may also be increased. A length of about 2 μm for the nanowire channel 204 may be achievable provided the nanowire diameter is correspondingly big.

In the context of various embodiments, the term “resistive memory cell” may include a memory cell of any kind which may be switched between two or more states exhibiting different resistivity values.

In various embodiments, the resistive memory cell 206 may include an electrode and wherein the nanowire transistor 202 and the resistive memory cell 206 may be configured such that the electrode includes one end portion of the nanowire channel 204. This may mean that the resistive memory cell 206 may be arranged towards or at the end portion of the nanowire channel 204. The electrode may serve as a bottom electrode (BE) of the resistive memory cell 206.

In various embodiments, the end portion of the nanowire channel 204 may include a top wall (or top surface) and/or one or two sidewalls of the nanowire transistor 202.

In various embodiments, the end portion of the nanowire channel 204 may include an implanted region, a silicide region or a metallic region.

As a non-limiting example, the implanted region at the end portion of the nanowire channel 204 may be a region implanted with dopants, or in other words a doped region.

As a non-limiting example, a silicide region at the end portion of the nanowire channel 204 may be formed by depositing a metal layer on the end portion of the nanowire channel (e.g. a silicon (Si) nanowire) 204, which may then be subjected to a heat treatment, for example using a rapid thermal annealing process, in order to form the silicide region, for example in the form of a metal silicide. In the context of various embodiments, the silicide region may include a material including but not limited to nickel silicide (NiSi), titanium silicide (TiSi₂), cobalt silicide (CoSi₂), nickel-platinum silicide (NiPtSi) or nickel-germanosilicide (NiGeSi).

In the context of various embodiments, the metallic region at the end portion of the nanowire channel 204 may include a material at least substantially similar to that of the silicide region as described above.

In various embodiments, the nanowire transistor 202 may further include a substrate (e.g. a silicon (Si) substrate) and wherein the longitudinal axis of the nanowire channel 204 may extend at an angle to the surface of the substrate. In one non-limiting example, the longitudinal axis of the nanowire channel 204 may extend at right angle or orthogonally to the surface of the substrate. This may mean that the nanowire channel 204 may be a vertical nanowire channel 204.

In the context of various embodiments, the nanowire channel 204 may extend monolithically from the substrate. This means that the substrate and the nanowire channel 204 may be a monolithic (single) structure. The nanowire channel 204 may extend continuously from the substrate. The nanowire channel 204 may extend at least substantially perpendicular to a surface of the substrate. As a non-limiting example, a substrate may be provided and portions of the substrate may be removed, for example based on pattering and etching, so as to form a nanowire channel 204 monolithically integrated with the substrate.

In various embodiments, the nanowire transistor 202 may further include a diffusion region and the diffusion region of the nanowire transistor 202 may be formed in the substrate. The diffusion region may extend into the nanowire channel 204. The diffusion region may be a doped region, for example doped with doping atoms of a first conductivity type or a second conductivity type.

In various embodiments, the nanowire transistor 202 may further include a further diffusion region formed from the end portion of the nanowire channel 204. The further diffusion region may be a doped region, for example for example doped with doping atoms of a first conductivity type or a second conductivity type.

In various embodiments, the diffusion region and the further diffusion region of the nanowire transistor 202 may be spaced apart from each other, for example with a portion (e.g. central portion) of the nanowire channel 204 in between.

In the context of various embodiments, the doping atoms of the first conductivity type (the second conductivity type) may be of a p-conductivity type such that a material doped with such doping atoms may be p-doped while the doping atoms of the second conductivity type (the first conductivity type) may be of an n-conductivity type such that a material doped with such doping atoms may be n-doped.

The term “p-doped” may mean a host material that is doped with doping atoms that may accept weakly-bound outer electrons from the host material, thereby creating vacancies left behind by the electrons, known as holes. Such doping atoms are also generally referred to as acceptor atoms.

The term “n-doped” may mean a host material that is doped with doping atoms that may provide extra conduction electrons to the host material, thereby resulting in an electrically conductive n-doped host material with an excess number of mobile electrons (negatively charged carriers). Such doping atoms are also generally referred to as donor atoms.

In the context of various embodiments, where the host material may be for example silicon, which is a Group IV element, the host material may be doped or implanted with Group III doping atoms or elements, for example boron (B), aluminum (Al) or gallium (Ga), to form a p-doped material, or doped or implanted with Group V doping atoms or elements, for example phosphorus (P), arsenic (As) or antimony (Sb), to form an n-doped material.

In the context of various embodiments, doping may be carried out with a dopant concentration of between about 1×10¹⁷/cm⁻³ to about 5×10²⁰/cm⁻³.

In various embodiments, the nanowire transistor 202 may further include a gate (G) region or terminal formed around the nanowire channel 204 between the diffusion regions (i.e. between the diffusion region and the further diffusion region of the nanowire transistor 202).

In the context of various embodiments, the nanowire transistor 202 may include a three-terminal vertical gate-all-around (GAA) transistor. This may mean that a gate (G) region may be formed around the nanowire channel 204. A gate contact may be coupled to the gate region. The GAA transistor may include a first source/drain terminal formed from or coupled to the end portion of the nanowire channel 204 and a second source/drain terminal formed from or coupled to an opposite end portion of the nanowire channel 204. A first source/drain contact may be coupled to the first source/drain terminal, and a second source/drain contact may be coupled to the second source/drain terminal.

In various embodiments, the first source/drain terminal may be coupled to the resistive memory cell 206. The first source/drain terminal may be coupled to a bit line (BL). This may mean that the resistive memory cell 206 may be arranged proximal to the bit line. The second source/drain terminal may be coupled to a source line (SL). The gate region or terminal may be coupled to a word line (WL).

In the context of various embodiments, the nanowire transistor 202 may be configured as a selection device (or access device) of the resistive memory cell 206. This may mean that the nanowire transistor 202 may be activated or switched on so that an electrical signal may be applied to the resistive memory cell 206 so as to select the resistive memory cell 206 for reading information from the resistive memory cell 206 or writing information to the resistive memory cell 206.

In the context of various embodiments, the nanowire transistor 202 may include a transistor selected from the group of transistors consisting of a junction based enhancement mode field effect transistor, a junction-less depletion mode field effect transistor and a tunneling field effect transistor.

In the context of various embodiments, the resistive memory cell 206 may further include a dielectric layer arranged over the electrode (e.g. bottom electrode) and a further electrode arranged over the dielectric layer. The further electrode may serve as a top electrode (TE) of the resistive memory cell 206.

In the context of various embodiments, the dielectric layer may include a resistive changing material which may change its resistance as a result of a change in its resistivity. The dielectric layer may serve as a switching dielectric or material.

In the context of various embodiments, the dielectric layer may include a material selected from the group of dielectric materials consisting of hafnium oxide (HfO₂), titanium oxide (TiO₂), aluminium oxide (Al₂O₃) and tantalum oxide (Ta₂O₅). Other oxides such as nickel oxide (NiOₓ) or tungsten oxide (WOₓ) may also be used. The dielectric layer may be a single layer or have a multilayer structure including one or more transition metal oxides, including the materials as described above.

In the context of various embodiments, the further electrode may include a material including but not limited to platinum (Pt), tungsten (W), nickel (Ni), aluminum (Al), titanium nitride (TiN), tantalum nitride (TaN), hafnium nitride (HfN), aluminium nitride (AlN), or tungsten nitride (WN).

In the context of various embodiments, the resistive memory cell 206 may include a memory cell selected from the group consisting of: a phase change memory cell; a conductive bridging memory cell; and a magnetoresistive memory cell.

In the context of various embodiments, the resistive memory cell 206 may change its resistance as a result of a change in its resistivity.

In the context of various embodiments, the term “coupled” may include electrical coupling and/or mechanical coupling. In the context of various embodiments, the term “coupled” may include a direct coupling and/or an indirect coupling. For example, two components being coupled to each other may mean that there is a direct coupling path between the two components and/or there is an indirect coupling path between the two components, e.g. via one or more intervening components.

In the context of various embodiments, the term “source/drain terminal” of a transistor may refer to a source terminal or a drain terminal. As the source terminal and the drain terminal of a transistor are generally fabricated such that these terminals are geometrically symmetrical, these terminals may be collectively referred to as source/drain terminals. In various embodiments, a particular source/drain terminal may be a “source” terminal or a “drain” terminal depending on the voltage to be applied to that terminal. Accordingly, the terms “first source/drain terminal” and “second source/drain terminal” may be interchangeable.

Various embodiments may also provide a non-volatile memory arrangement. The non-volatile memory arrangement may include a plurality of nanowire transistors, each nanowire transistor including a nanowire channel, and a plurality of resistive memory cells, wherein a respective resistive memory cell is arranged adjacent to a respective nanowire transistor and in alignment with a longitudinal axis of the nanowire channel of the respective nanowire transistor. The non-volatile memory arrangement may further include a plurality of conductive lines electrically coupled to the plurality of nanowire transistors and the plurality of resistive memory cells.

Each nanowire channel, each nanowire transistor, and each resistive memory cell of the non-volatile memory arrangement of various embodiments may be as correspondingly described in the context of the non-volatile memory device 200 of FIG. 2A.

In various embodiments, the plurality of conductive lines may include a plurality of first conductive lines, wherein a respective first conductive line of the plurality of first conductive lines may be coupled to a respective resistive memory cell, and a plurality of second conductive lines, wherein a respective second conductive line of the plurality of second conductive lines may be coupled to a respective nanowire transistor, for example coupled to a gate region of the respective nanowire transistor. The plurality of first conductive lines may be bit lines (BLs). The plurality of second conductive lines may be word lines (WLs)

FIG. 2B shows a flow chart 220 illustrating a method of forming a non-volatile memory device, according to various embodiments.

At 222, a nanowire transistor including a nanowire channel is formed.

At 224, a resistive memory cell is formed adjacent to the nanowire transistor and in alignment with a longitudinal axis of the nanowire channel.

Various embodiments may provide RRAM devices with completely CMOS compatible materials. These devices may be easily integrated with a vertical transistor as a selector with 4F² footprint for low-cost and high density NVM applications.

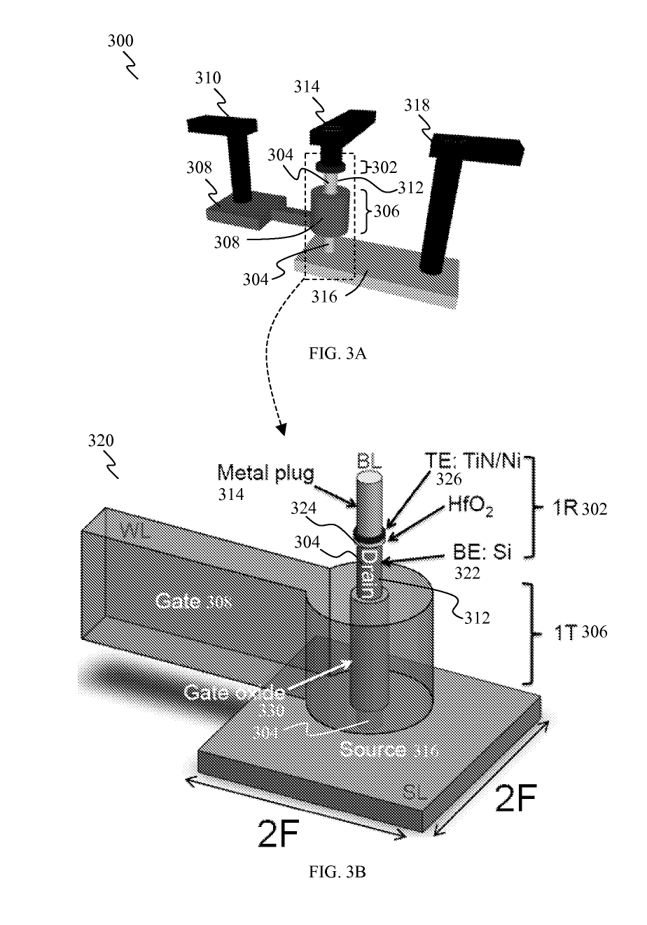

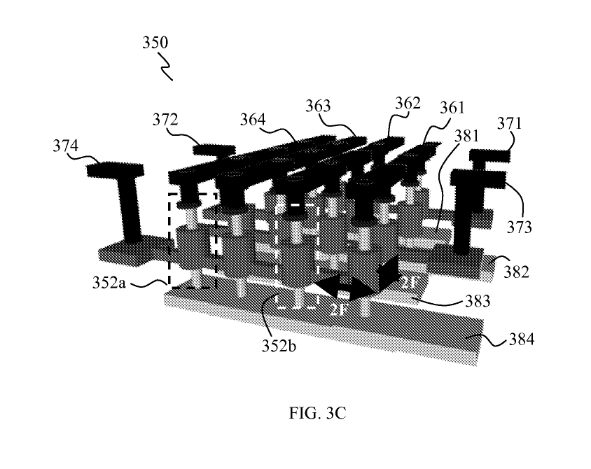

FIG. 3A shows a schematic perspective view of a non-volatile memory device 300, according to various embodiments. As illustrated in FIG. 3A, the RRAM cell (resistive memory cell) 302 (1R) may be directly formed or stacked on top of or over a nanowire (e.g. Si nanowire) 304 and a nanowire field effect transistor (FET) 306 (1T) without occupying any planar space. This may mean that the non-volatile memory device 300 may have a vertical nanowire (VNW) 1T1R with the RRAM cell 302 directly built on top of the nanowire 304. The transistor 306 may be a gate all around (GAA) MOSFET. The non-volatile memory device 300 as shown in FIG. 3A represents a single unit 1T1R arrangement having a 4F² footprint.

A gate (G) terminal or region 308 of the transistor 306 may be arranged with at least a portion at least substantially surrounding the nanowire 304, thereby providing a GAA configuration. The gate terminal 308 may be coupled to a gate contact 310. A drain (D) terminal 312 may be coupled to or formed at one end portion of the nanowire 304, where a drain contact 314 may be coupled to the drain terminal 312. The drain contact 314 may also be coupled to the RRAM cell 302. A source (S) terminal 316 may be coupled to or formed at an opposite end portion of the nanowire 304, where a source contact 318 may be coupled to the source terminal 316.

In various embodiments, each of the gate contact 310, drain contact 314 and source contact 318 may be a metal plug. The gate contact 310 may be coupled to a word line (WL), the drain contact 314 may be coupled to a bit line (BL) while the source contact 318 may be coupled to a source line (SL).

FIG. 3B shows a schematic perspective view of a non-volatile memory device 320, according to various embodiments. As a non-limiting example, the nanowire 304 may be a silicon (Si) nanowire, and which may serve as the bottom electrode (BE) 322 of the RRAM cell 302. The RRAM cell 302 may include a dielectric layer (e.g. HfO₂) 324 arranged over the bottom electrode 322. The RRAM cell 302 may further include a top electrode (TE) 326 arranged over the dielectric layer 324. The top electrode 326 may include or may be a combination of TiN/Ni. In various embodiments, the transistor (e.g. VNW MOSFET) 306 may include a gate oxide 330 at least substantially surrounding a portion of the nanowire 304, and sandwiched between the nanowire 304 and the gate terminal 308.

As shown in FIG. 3B, a vertical GAA nanowire transistor 306 may be integrated with a RRAM cell 302 vertically on the same nanowire 304, where the bottom electrode 322 of the RRAM cell 302 may share the same nanowire (e.g. silicon nanowire) 304 with the drain (D) region 312 of the MOSFET 306.

FIG. 3C shows a schematic perspective (3D) view of a non-volatile memory arrangement 350, according to various embodiments. The non-volatile memory arrangement 350 may include an array of non-volatile memory devices, for example as represented by 352 for a 1T1R non-volatile memory device. Each non-volatile memory device 352 may be of the embodiments of FIGS. 3A and/or 3B. As a non-limiting example, FIG. 3C shows a non-volatile memory arrangement 350 having a 4×4 array with a 4F² footprint, where the period or pitch between adjacent single unit cells is 2F.

The non-volatile memory arrangement 350, including 4×4 1T1R non-volatile memory devices may be coupled to four bit lines, BL1 361, BL2 362, BL3 363, BL4 364, four word lines, WL1 371, WL2 372, WL3 373, WL4 374, and four source lines, SL1 381, SL2 382, SL3 383, SL4 384. As a non-limiting example, the single unit cell 352a is coupled to BL4 364, WL4 374 and SL4 384, while the single unit cell 352b is coupled to BL2 362, WL4 374 and SL4 384.

As shown in FIG. 3C, the source terminal/contact of a respective single unit cell (e.g. 352a, 352b) is coupled to a source line. The gate terminal/contact of the respective single unit cell (e.g. 352a, 352b) is coupled to a word line. The drain terminal/contact of the respective single unit cell (e.g. 352a, 352b) is coupled to a bit line. The bit lines, BL1 361, BL2 362, BL3 363, BL4 364, may be metal lines connecting the top electrodes of the RRAM cells. The word lines, WL1 371, WL2 372, WL3 373, WL4 374, may be the transistor gate poly lines.

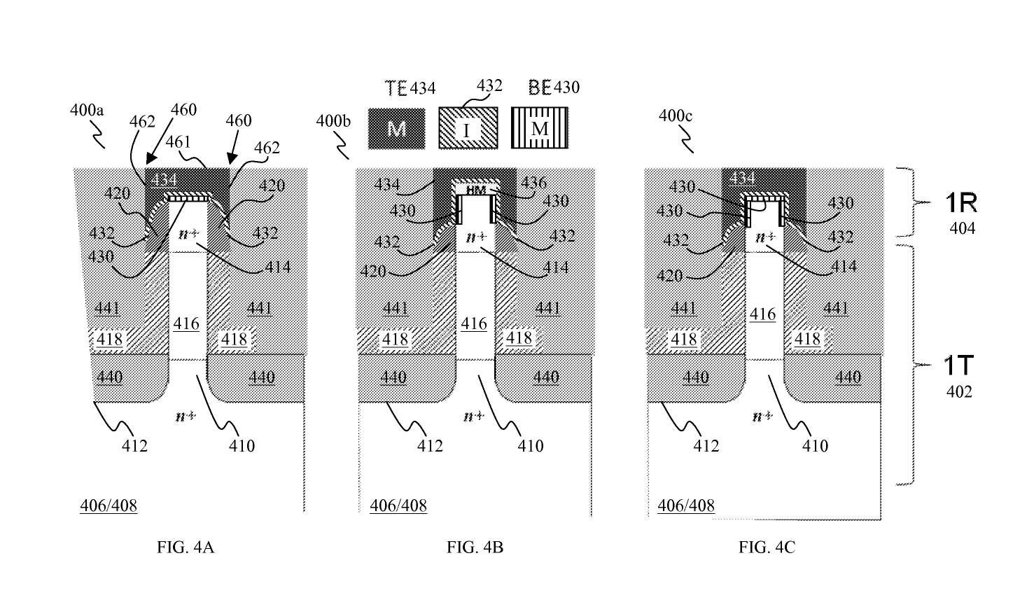

FIGS. 4A to 4C respectively show schematic cross sectional views of non-volatile memory devices 400a, 400b, 400c, according to various embodiments. Each non-volatile memory device 400a, 400b, 400c, may be a 1T1R non-volatile memory device, including a transistor (1T) 402 and a RRAM cell (1R) 404. Using the non-volatile memory device 400a as a non-limiting example, the nanowire transistor 402 may include a nanowire or nanowire channel 410. The nanowire transistor 402 may include a substrate 406 where the nanowire or nanowire channel 410 may extend from the substrate 406, for example extend perpendicular to a surface 412 of the substrate 406. The transistor 402 may include a diffusion region 408, for example an n+ doped region, formed in at least a portion of the substrate 406. The diffusion region 408 may extend partially into the nanowire channel 410, proximal to the bottom end portion of the nanowire channel 410. The transistor 402 may further include a further diffusion region 414, for example an n+ doped region, formed from the top end portion of the nanowire channel 410. The nanowire channel 410 may include a central portion 416, sandwiched in between the diffusion regions 408, 414, where the central portion 416 may be doped with dopants of a conductivity type opposite to that of the diffusion regions 408, 414, i.e. p-doped. The non-volatile memory device 400a may include a spacer 420 arranged at least substantially surrounding the diffusion region 414. In various embodiments, the spacer 420 may include any dielectric materials, for example an oxide material (e.g. SiO₂, Al₂O₃) a nitride material (e.g. SiN), etc. From a process perspective, SiN may be chosen as it has a good etch selectivity with an underneath or underlying SiO₂ layer. From a device perspective, low-k dielectric materials may be chosen to avoid high parasitic capacitance or minimise the parasitic capacitance.

The transistor 402 may include a gate (G) region 418 formed around the nanowire channel 410 between the diffusion regions 408, 414. This may mean that the gate region 418 may be formed at least substantially surrounding the central portion 416 of the nanowire channel 410. Therefore, the transistor 402 may be a vertical gate-all-around (GAA) transistor.

The RRAM cell 404 may be arranged adjacent to the nanowire transistor 402 and in alignment with a longitudinal axis of the nanowire channel 410. The RRAM cell 404 may be a self-aligned cell. The RRAM cell 404 may include a metal-insulator (dielectric)-metal (M-I-M) configuration.

The RRAM cell 404 may include a bottom electrode (BE) 430, for example in the form of a silicide layer or region (Si/silicide), where the silicide region 430 may be formed at the top end portion of the nanowire channel 410. The silicide region 430 may be formed at a top wall of the nanowire transistor 402.

The RRAM cell 404 may further include a dielectric layer 432 arranged over the bottom electrode 430. The dielectric layer 432 may also be arranged over the spacer 420. The RRAM cell 404 may further include a top electrode (TE) 434, for example in the form of a metallic layer, arranged over the dielectric layer 432.

The non-volatile memory device 400a may include one or more passivation layers 440, 441, at least substantially surrounding the transistor 402 and the RRAM cell 404.

The configuration of the non-volatile memory device of various embodiments, including the non-volatile memory device 400a, may provide reduced contact area, which may lead to a reduction in switching current (low power).

For the non-volatile memory device of various embodiments, including the non-volatile memory device 400a, the corners 460 of the top electrode (TE) 434, between the top flat portion or surface 461 and the vertical sidewall portions 462 may be rounded, rather than at 90° which may result in sharp edges and hence local field enhancement. Where the corners 460 have sharp edges, the breakdown paths that may be formed during the “forming” process (e.g. the process of forming the conduction path for SET) may not be spatially random, as they may concentrate at the sharp corners. In order to avoid or minimise this, some degree of over etch may be applied during the spacer etch so as to round the sharp corners. As the RRAM is no longer 2D parallel plate, such a corner effect may or may not improve the memory characteristics, but this effect may nevertheless be suppressed if necessary.

The non-volatile memory device 400b as illustrated in FIG. 4B may be similar to the non-volatile memory device 400a, except that the bottom electrode (BE) 430, for example in the form of a silicide layer or region and/or a metallic region (Si/silicide/metal), may be formed on one or more sidewalls of the nanowire transistor 402. In one non-limiting example, the bottom electrode (BE) 430 may be formed around the sidewalls of the nanowire transistor 402, providing a cylindrical RRAM cell 404, which may offer forming and SET voltage reduction. In addition, the non-volatile memory device 400b may include a spacer 420 arranged at least substantially surrounding a portion of the diffusion region 414, where the portion of the diffusion region 414 may be free of the bottom electrode (BE) 430. The non-volatile memory device 400b further includes a hard mask (HM) layer 436, which may also serve as a bottom electrode (BE).

The configuration of the non-volatile memory device of various embodiments, including the non-volatile memory device 400b, may provide increased surface field, which may lead to a low forming voltage. In addition, the RRAM cell area may be tunable.

The non-volatile memory device 400c as illustrated in FIG. 4C may be similar to the non-volatile memory device 400a, except that the bottom electrode (BE) 430 may be formed at a top wall and on one or more sidewalls of the nanowire transistor 402. In addition, the non-volatile memory device 400c may include a spacer 420 arranged at least substantially surrounding a portion of the diffusion region 414, where the portion of the diffusion region 414 may be free of the bottom electrode (BE) 430. The transistor 402 of the non-volatile memory device of various embodiments, including the non-volatile memory device 400c, may be a junction-less FET or a tunneling FET.

In various embodiments, as shown in FIGS. 4A to 4C, the height of the spacer 420 may be varied so as to tune the size of the RRAM cell 404.

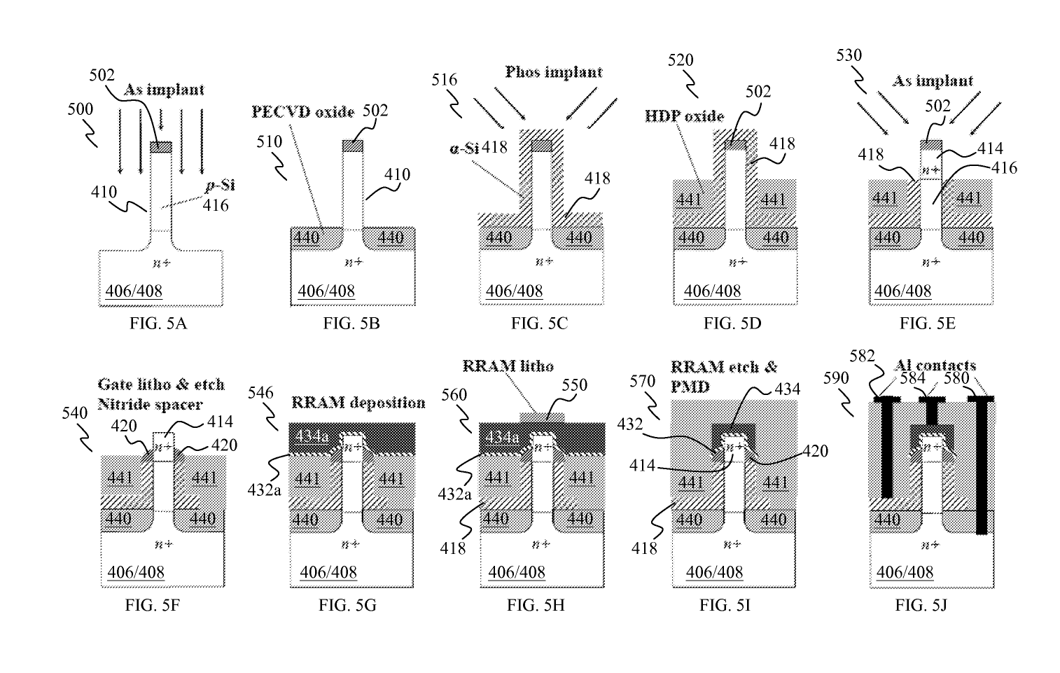

FIGS. 5A to 5J show, as cross-sectional views, various processing stages of a method of forming a non-volatile memory device, according to various embodiments, illustrating the device fabrication process flow for forming a vertical nanowire (VNW) 1T1R memory cell. While FIGS. 5A to 5J illustrate the fabrication of a single 1T1R memory cell, it should be appreciated that a plurality or array of 1T1R memory cells may be fabricated using a similar process.

A silicon (Si) substrate may first be provided. The Si substrate may include a basic doping, for example p-doped to form p-Si. One or more Si nanowires or nanowire channels may then be defined from the Si substrate, for example using lithography and etching processes. A bottom implantation process may then be carried out after the nanowire definition, for example using arsenic (As) dopants to form an n+ doped region in the substrate so as to define a diffusion region towards the bottom end portion of the nanowire proximal to the substrate. As shown in FIG. 5A, a structure 500 may be obtained, including a nanowire 410 having a p-Si central portion 416, where the Si nanowire 410 may extend from the substrate 406, where at least a portion of the substrate is implanted with As to define a diffusion region 408. A mask layer or resist layer 502 may be maintained on top of the nanowire 410, for example after the process for defining the nanowire 410, so as to mask the nanowire 410 during the As implantation process to define the diffusion region 408. In a non-limiting example, the mask layer 502 may be a high quality low-pressure chemical vapour deposition (LPCVD) silicon nitride (SiN) which acts as the hard mask for the nanowire etch. The mask layer 502 may be maintained on the Si nanowire 410 or removed to free the top region or tip of the Si nanowire 410 as the bottom electrode (BE).

Subsequently, as shown in FIG. 5B, an isolation oxide 440, for example formed using plasma-enhanced chemical vapor deposition (PECVD), may be deposited towards the bottom end portion of the nanowire 410 over the diffusion region 408 to form the structure 510. The PECVD oxide 440 may cover the diffusion region 408.

Then, as shown in FIG. 5C, a gate oxide/amorphous silicon (α-Si) stack 418 may be deposited over the nanowire 410 and the isolation oxide 440, followed by gate shallow implantation using phosphorus (P) dopants, to form the structure 516. The α-Si stack 418 may at least substantially surround the nanowire 410.

An isolation oxide, for example formed using high density plasma (HDP) oxide deposition, may be deposited over the structure 516. The HDP isolation oxide may then be wet etched back to form an etch mask for the α-Si stack 418 exposed from the tip of the nanowire 410. As shown in FIG. 5D, a structure 520 may be obtained, including the HDP isolation oxide 441 which has been etched back to expose the top end portion of the nanowire 410.

Subsequently, as shown in FIG. 5E, the α-Si stack 418 may be wet etched to expose the top end portion or the tip of the nanowire 410, followed by top angle implantation, for example using arsenic (As) dopants to form an n+ doped region towards the top end portion of the nanowire 410 so as to define a further diffusion region 414, with the central portion 416 of the nanowire 410 sandwiched in between the two diffusion regions 408, 414. The α-Si stack 418 may at least substantially surround the central portion 416 of the nanowire 410 and may define a gate (G) region of a nanowire transistor. The structure 530 may therefore be formed.

A first nitride spacer (e.g. SiN) may then be formed, followed by stripping of oxide 441, at least partially, and gate lithography and etching. The first nitride spacer may be employed as the protection layer during the removal of oxide HDP isolation oxide 441. After gate lithography and etching, HDP oxide deposition may then be performed to deposit a passivation oxide layer (e.g. similar to oxide 441), followed by chemical mechanical polishing/planarization (CMP), stopping at the nitride hard mask 502, where the nitride hard mask 502, as the CMP stopping layer, has a certain selectivity during SiO₂ CMP and prevent or at least minimise the Si nanowire being over-polished. Time may also be used as a parameter to control the polishing but this may have a lower process margin. Therefore, the SiN hard mask 502 as the stopping layer may be suitable to avoid or minimise over polishing.

Subsequently, wet etch back of the deposited oxide may be carried out to expose the SiN hard mask 502 and at least part of the first nitride spacer. The HDP SiO₂ deposition, CMP and etch back may form a mask that exposes the area where a RRAM cell is to be formed from the top of the nanowire 410 in a later step, and to protect the rest of the structures like gate poly-Si, the bottom portion corresponding to the second gate spacer (e.g. 420) and the nanowire channel 410.

In embodiments where the top portion of the nanowire 410 is to be used as the bottom electrode (BE), nitride removal may be performed to remove or etch away the SiN hard mask 502 and the first SiN nitride spacer in a phosphoric acid (H₃PO₄) wet etch. In alternative embodiments, the SiN hardmask 502 may be maintained, for example as illustrated in FIG. 4B where there is a hard mask (HM) layer 436.

Thereafter, a second nitride spacer (e.g. SiN) may be deposited over the exposed nanowire sidewalls and top surface of the nanowire 410 after removal of the SiN hardmask 502 and the first SiN spacer, followed by a spacer etch to define the Si portion of the nanowire 410 that may be exposed to be used to define the bottom electrode area. As shown in FIG. 5F, a structure 540 may be obtained, including a nitride spacer (the second nitride spacer as described above) 420 formed at least substantially surrounding a portion of the diffusion region 414, with the isolation oxide 441 extended to cover at least a portion of the nitride spacer 420. The α-Si stack 418 may be etched back on one side of the nanowire 410 as part of the gate lithography and etching process.

A dielectric layer, as part of a RRAM cell, may then be formed, followed by metal deposition to deposit a metal layer over the dielectric layer so as to serve as the top electrode corresponding to the RRAM cell. A shown in FIG. 5G, a structure 546 may be obtained, with a RRAM cell defined over the nanowire transistor, including a dielectric layer 432a and a metal layer 434a formed over the nanowire 410 and the nitride spacer 420.

As shown in FIG. 5H, cell lithography may be performed to deposit a mask layer 550 for defining the top electrode in a subsequent step, after the deposition of the second nitride spacer 420, the dielectric layer 432a and the metal layer 434a. Therefore, a structure 560 may be obtained. The mask layer that is used to define the SiN hard mask 502 and the Si nanowire 410 may be used to define the RRAM bottom electrode, including for example for forming the RRAM bottom electrode of the non-volatile memory device 400b (FIG. 4B).

Thereafter, as shown in FIG. 5I, a RRAM etch process may be carried out via the mask layer 550 to define the top electrode 434 and the dielectric layer 432 for the RRAM cell, thereby forming the structure 570. The diffusion region 414 may serve as the bottom electrode for the RRAM cell. Pre-metal dielectric (PMD) and contact formation may also be carried out. The contact formation may mean forming of through vias through the oxide layer 441, for example for respective contacts with the diffusion region 408, the α-Si stack 418 and the top electrode 434.

Subsequently, as shown in FIG. 5J, metallization with aluminum (Al) may be carried out to form Al contacts, for example Al contact 580 coupled to the diffusion region 408, Al contact 582 coupled to the α-Si stack 418 and Al contact 584 coupled to the top electrode 434. Therefore, a non-volatile memory device 590 with a RRAM cell, a nanowire transistor and Al contacts 580, 582, 584, may be formed.

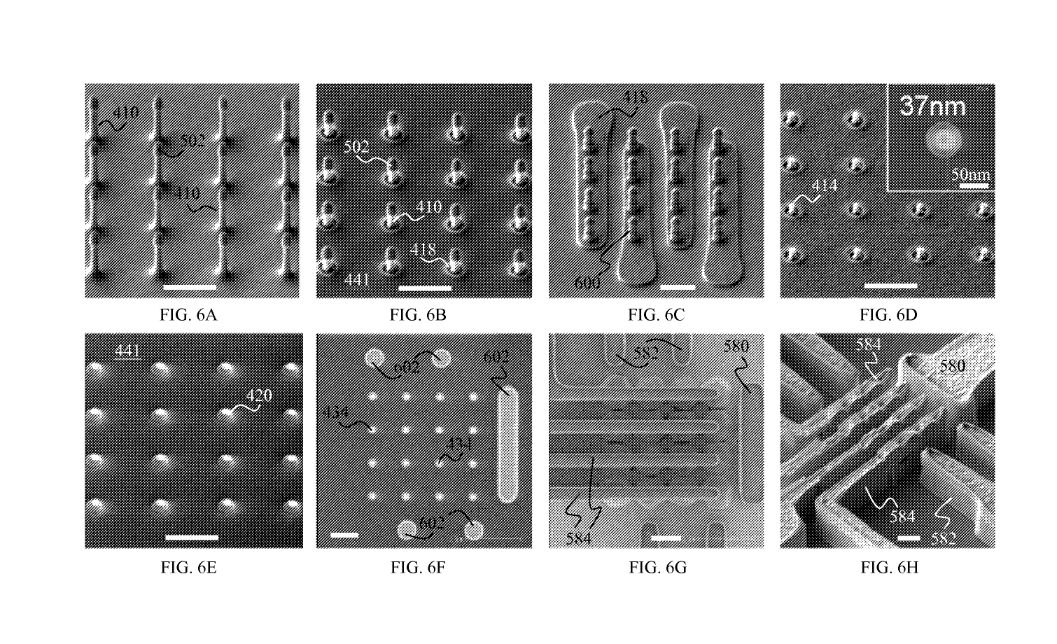

FIGS. 6A to 6H show SEM micrographs of a 4×4 array of non-volatile memory devices in various process steps, according to various embodiments. FIG. 6A shows a 4×4 array of nanowires 410, with a respective mask layer 502, that may be formed, corresponding to the processing stage for obtaining the structure 500 of FIG. 5A but prior to As implantation. FIG. 6B shows a structure that may be formed, including exposed tips of the nanowires 410 after α-Si 418 wet etch, corresponding to the structure 530 of FIG. 5E but prior to As implantation.

FIG. 6C shows a structure that may be formed after a gate lithography and etching process with a first nitride spacer 600 covering at least part of the nanowire 410. FIG. 6D shows a structure that may be formed after nitride removal, e.g. removal of the SiN hardmask 502 as well as the first SiN spacer after a wet chemical etch in phosphoric acid (H₃PO₄), illustrating a nanowire diameter of approximately 37 nm, which may function as the memory cell (RRAM cell) bottom electrode. FIG. 6E shows a structure that may be formed after deposition of a second nitride spacer 420, and a HDP oxide (e.g. SiO₂) 441 that is etched back. FIG. 6F shows a top view of a structure obtained after contact lithography and contact etching, showing the top electrode 434 and through vias 602. FIG. 6G shows a top view of a structure obtained after metal lithography to connect the top electrodes 434 of the memory cells as bit lines 584, to form contacts 582 connecting to the gate (G) region 418 of the nanowire transistor and contact 580 connecting to the diffusion region 408 (see also FIG. 5J). While not clearly shown, there is resist on the structure corresponding to FIG. 6G for the purpose of metal etching, where FIG. 6H shows a structure obtained after metal etch.

In various embodiments, the vertical NW transistor fabrication process steps may be as shown in FIGS. 5A-5G and FIGS. 6A-6C. After completing the nanowire transistor, the wafer may be planarized by oxide deposition and CMP. The nitride hard mask (e.g. SiN hard mask 502) may then be removed to expose the doped nanowire tip, which may serve as the drain terminal of the nanowire transistor. In various embodiments, this nanowire tip for the smallest design may have a diameter of about 37 nm, as shown in FIG. 6D. A nitride spacer may then be formed to protect the exposed nanowire sidewalls from making contact to the RRAM cell (FIG. 6E). The PVD HfO₂, Ni and TiN may be deposited as the memory cell (RRAM cell), followed by cell lithography and etching (FIG. 5H). The whole process may be completed with contact opening (FIG. 6F) and Al metallization (FIGS. 6G and 6H)).

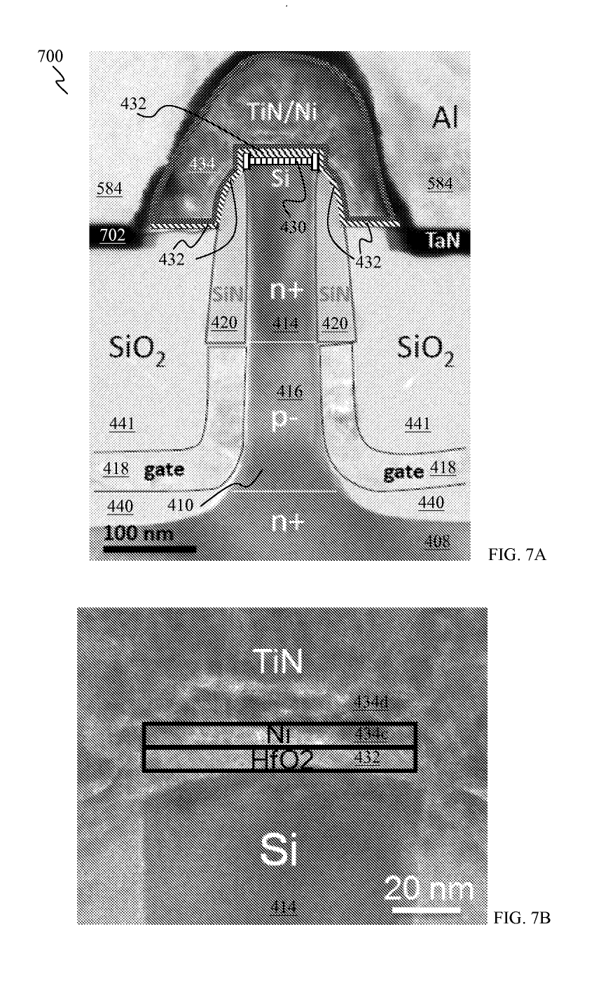

FIG. 7 shows a transmission electron microscopy

(TEM) micrograph of a fabricated 1T1R memory cell 700, according to various embodiments. The memory cell 700 includes a tantalum nitride (TaN) layer 702, which is a diffusion barrier for the Al metallization (e.g. for forming the Al contact 584) or Al/Cu metallization. The TaN layer 702 may be part of the metallization. FIG. 7B is the high resolution TEM image of the memory cell 700, towards the tip of the nanowire channel 410, which includes n⁺-Si 414/HfO₂ 432/Ni 434c/TiN 434d.

The results and analysis of the non-volatile memory devices of various embodiments will now be described by way of the following non-limiting examples.

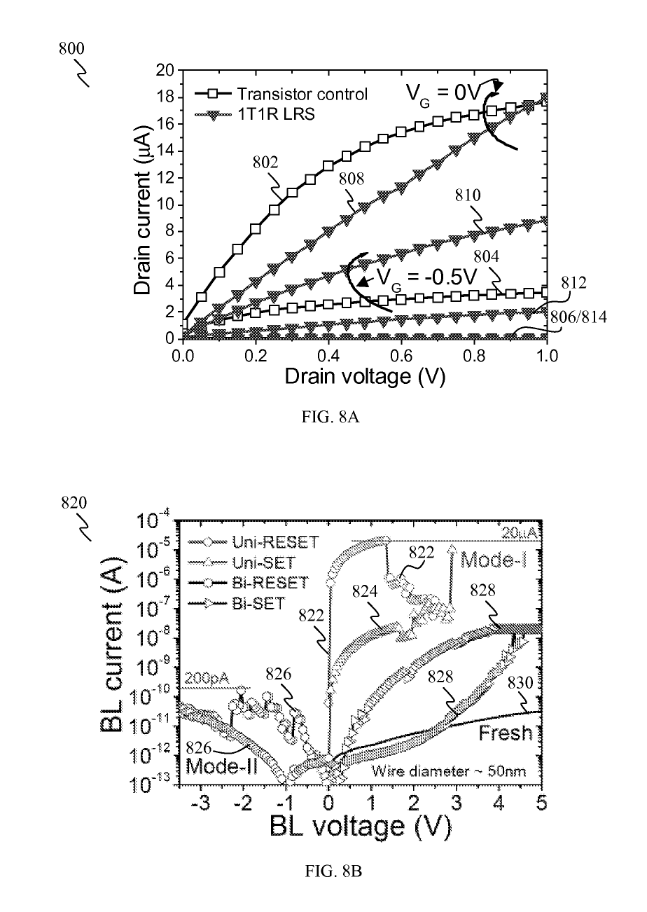

FIG. 8A shows a plot 800 of the transistor output characteristics of a control wafer without a memory cell and a 1T1R wafer with a RRAM cell in low resistance state (LRS), according to various embodiments. The plot 800 illustrates the results 802, 804, 806 for the transistor control under various gate voltages (e.g. V_{G}=0V; −0.5 V), and the results 808, 810, 812, 814 for the 1T1R LRS device under various gate voltages, V_{G}. The results show that there is no or minimal impact on the drive capability or drain current after adding the memory cell.

FIG. 8B shows a plot 820 illustrating memory cell operations under unipolar and bipolar modes at V_{WL}=V_{SL}=0V, according to various embodiments, showing different types of resistive switching: Mode-I unipolar (RESET result 822 (circular data points), SET result 824 (top pointing triangular data points)); and Mode-II ultralow current bipolar (RESET result 826 (hexagonal data points), SET result 828 (right pointing triangular data points)). The line indicated as “Fresh” 830 refers to the I-V sweep of a fresh device before forming. “Forming” here refers to the initial creation of the conduction path, e.g. the first SET process. The current compliance during the forming process may be kept at approximately 1.0 μA for Mode I and approximately 10 nA for Mode II. The RESET currents for Mode I and Mode II may be approximately 20 μA and 200 pA, respectively. The results 822, 824, 826, 828 show that the nanowire transistor (VNW transistor) may supply enough drive current to the memory cell owing to the small size of the memory cell.

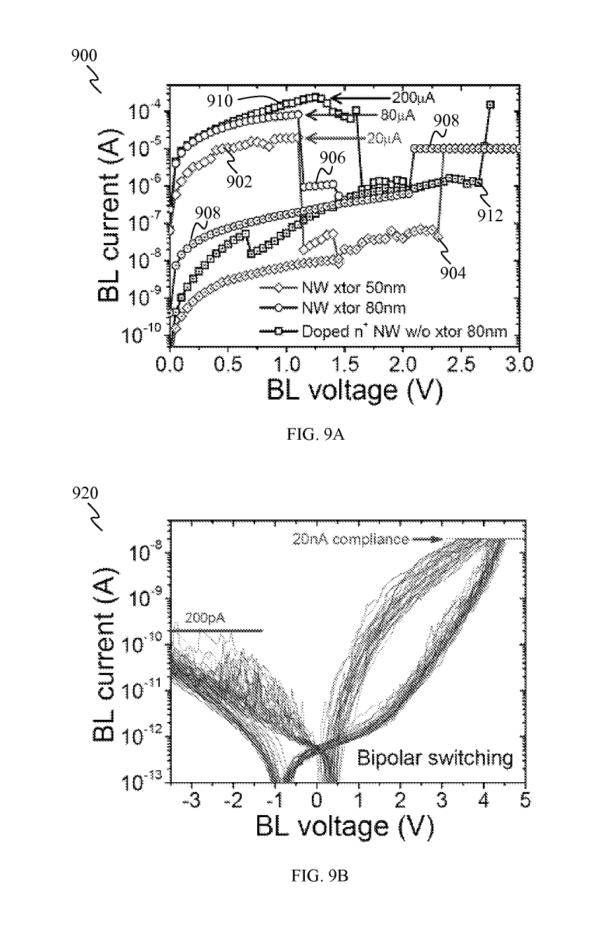

FIG. 9A shows a plot 900 of unipolar mode switching for an n⁺ doped nanowire (without FET) and 1T1R cells of different nanowire diameters, according to various embodiments. The plot 900 shows the results for SET and RESET under DC sweep for Mode-I unipolar switching. The plot 900 shows the RESET results 902, and SET results 904 (diamond-shaped data points) corresponding to a 1T1R cell with a nanowire transistor having a nanowire with a 50 nm diameter (NW xtor 50 nm), RESET results 906, and SET results 908 (circular data points) corresponding to a 1T1R cell with a nanowire transistor having a nanowire with a 80 nm diameter (NW xtor 80 nm), and RESET results 910, and SET results 912 (square-shaped data points) corresponding to an n⁺ doped nanowire (80 nm diameter) without FET (Doped n⁺ NW w/o xtor 80 nm).

The RESET current scales with nanowire diameter (e.g. drive current and bottom electrode area) under unipolar mode operations and is also proportional to the transistor current. The parasitic resistances/capacitances of nanowire transistors may also help to reduce the RESET current.

FIG. 9B shows a plot 920 of ultralow current bipolar mode switching. The switching power for SET is approximately <85 nW and RESET is approximately <0.7 nW (in comparison to 10 μA/30 μW and 20 μA/30 μW for unipolar mode), illustrating ultra-low RESET current under bipolar mode operations.

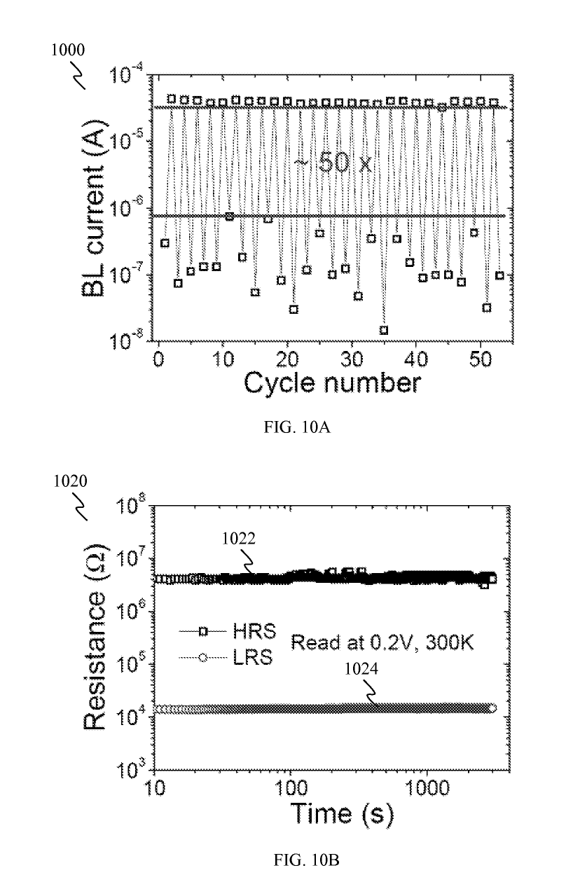

FIGS. 10A and 10B respectively show plots of DC endurance cycles and room temperature (RT) retention for unipolar mode switching. FIG. 10A shows a plot 1000 of 50 DC cycles of the RRAM cell under unipolar mode operation (V_{BL}=0.2V) while FIG. 10B shows its RT retention characteristics in high resistance state (HRS) 1022 and low resistance state (LRS) 1024.

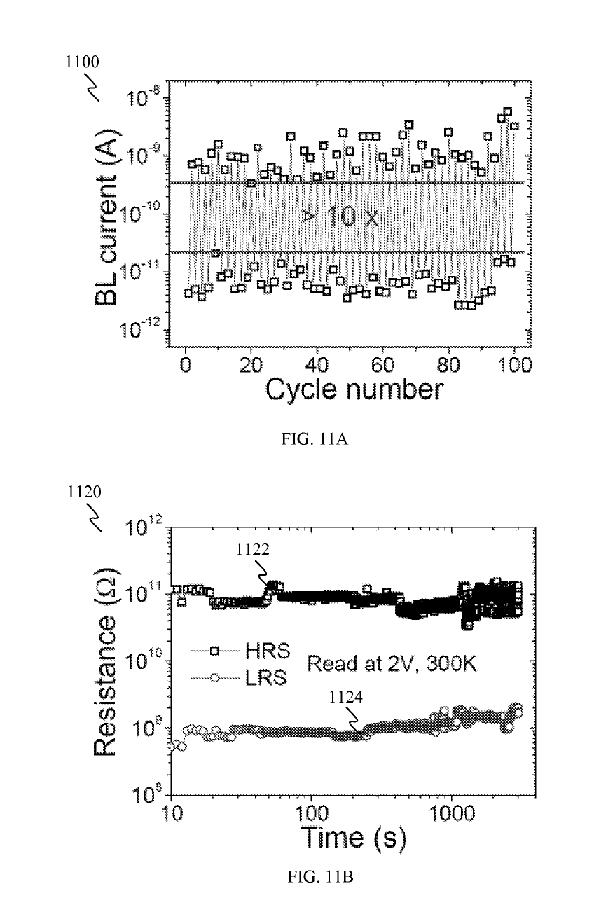

FIGS. 11A and 11B respectively show plots of DC endurance cycles and room temperature (RT) retention for ultralow current bipolar mode switching. FIG. 11A shows a plot 1100 of 100 DC cycles of the RRAM cell under ultralow bipolar mode operation (V_{BL}=2V) while FIG. 11B shows its RT retention characteristics in high resistance state (HRS) 1122 and low resistance state (LRS) 1124.

As described above, the non-volatile memory devices of various embodiments may have a 1T1R structure, with unipolar and bipolar modes of operation. The non-volatile memory devices may include a 1T1R structure with a vertical nanowire (VNW) FET with 4F² footprint, with bidirectional control of current. The resistive switching memory may be a two terminal device, having high endurance and retention even at <10 nm scale. The P/E voltage may be low, e.g. <3V. However, there may be challenges in that cycle to cycle and cell to cell variation may be high. The metal oxide RRAM of various embodiments may have a low P/E current, making them suitable for low power applications. The NVM in the 1T1R configuration of various embodiments may be tunable in size and/or architecture, and which may be either GAA or planar or both.

The process of forming the non-volatile memory device of various embodiments may be full CMOS compatible. The process may enable self-aligned silicon (Si) electrode, with tunable cell size. The process may require an additional mask. In addition, the resistive memory cell (e.g. RRAM cell) may be formed at the lowest possible level, which is metal-1, so as to be close to the transistor. This may provide the highest density as the metal-1 pitch may be almost as high as the transistor, and/or may enable the electrical current to communicate faster as the distance of the RRAM cell may be minimum to the transistor. Hence, there may be a low RC delay, referring to the speed of electrical signal communication in the metallization (e.g. Cu metallization). In contrast, conventionally, a RRAM cell is formed at the metal-4 level for example, resulting in a longer delay for communication between the transistor and the memory cell. The non-volatile memory devices of various embodiments may provide cell improvement over conventional memory devices, by offering a low program/erase (P/E) current, for example <20 μA, or which may be as low as FLASH memory.

The non-volatile memory devices of various embodiments may be fabricated on 32 nm technology node or beyond. It should be appreciated that other types of RRAM cells or RRAM cells with enhanced performance may be integrated in the non-volatile memory devices of various embodiments. In addition, it should be appreciated that the nanowire transistor may be replaced by or may be in the form of a tunneling FET/junction-less FET to achieve ultralow power circuit/reduce process complexity.

The non-volatile memory devices of various embodiments may be employed in applications including but not limited to low standby power and low operating voltage non-volatile memory (NVM), e.g. FLASH memory, solid-state drive for portable devices, and embedded NVM for microcontroller, among others.

Various embodiments may provide full CMOS compatible integration of RRAM with vertical GAA nanowire transistor with 4F² footprint. Excellent current scalability may be achieved with reduced nanowire diameters, making it ready for advanced technology nodes. The vertical nanowire CMOS platform of various embodiments, with ultralow switching current, may be promising for high-density low power RRAM integrations, including embedded memory.

The memory devices of various embodiments may provide one or more of the following features as compared to conventional devices and/or process: (1) the memory device may be based on filament/surface reaction based resistive switching memory; (2) the memory device may have three contacts: drain, gate (transistor) and top electrode (memory); (3) the memory device may be either sidewall GAA or planar capacitor on pillar top or both, thereby allowing flexibility in forming the memory device; (4) the memory device uses a transistor, which gives bidirectional current; (5) the memory device uses metal oxide RRAM which has both bipolar and unipolar modes of operation, and the P/E current may be very low and suitable for low power applications; and (6) the memory cell may be formed on the nanowire sidewall or planar pillar top or both, and where the size may be tuned by controlling the spacer etch, thereby allowing flexibility in forming the memory device.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

While the preferred embodiments of the devices and methods have been described in reference to the environment in which they were developed, they are merely illustrative of the principles of the inventions. The elements of the various embodiments may be incorporated into each of the other species to obtain the benefits of those elements in combination with such other species, and the various beneficial features may be employed in embodiments alone or in combination with each other. Other embodiments and configurations may be devised without departing from the spirit of the inventions and the scope of the appended claims.

1. A non-volatile memory device comprising:
a nanowire transistor comprising a nanowire channel; and
a resistive memory cell arranged adjacent to the nanowire transistor and in alignment with a longitudinal axis of the nanowire channel.

2. The non-volatile memory device of claim 1, wherein the resistive memory cell comprises an electrode and wherein the nanowire transistor and the resistive memory cell are configured such that the electrode comprises one end portion of the nanowire channel.

3. The non-volatile memory device of claim 2, wherein the end portion of the nanowire channel comprises a top wall and/or one or two sidewalls of the nanowire transistor.

4. The non-volatile memory device of claim 2, wherein the end portion of the nanowire channel comprises an implanted region, a silicide region or a metallic region.

5. The non-volatile memory device of claim 2, wherein the nanowire transistor further comprises a substrate and wherein the longitudinal axis of the nanowire channel extends at an angle to the surface of the substrate.

6. The non-volatile memory device of claim 5, wherein the nanowire transistor further comprises a diffusion region and the diffusion region of the nanowire transistor is formed in the substrate.

7. The non-volatile memory device of claim 6, wherein the nanowire transistor further comprises a further diffusion region formed from the end portion of the nanowire channel.

8. The non-volatile memory device of claim 7, wherein the nanowire transistor further comprises a gate region formed around the nanowire channel between the diffusion regions.

9. The non-volatile memory device of claim 1, wherein the nanowire transistor comprise a three-terminal vertical gate-all-around (GAA) transistor.

10. The non-volatile memory device of claim 1, wherein the nanowire transistor is configured as a selection device of the resistive memory cell.

11. The non-volatile memory device of claim 1, wherein the nanowire transistor comprises a transistor selected from a group of transistors consisting of a junction based enhancement mode field effect transistor, a junction-less depletion mode field effect transistor and a tunneling field effect transistor.

12. The non-volatile memory device of claim 2, wherein the resistive memory cell further comprises a dielectric layer arranged over the electrode and a further electrode arranged over the dielectric layer.

13. The non-volatile memory device of claim 1, wherein the resistive memory cell comprises a memory cell selected from a group consisting of: a phase change memory cell; a conductive bridging memory cell; and a magnetoresistive memory cell.

14. The non-volatile memory device of claim 12, wherein the dielectric layer comprises a material selected from a group of dielectric materials consisting of HfO₂, TiO₂, Al₂O₃ and Ta₂O₅.

15. A method of forming a non-volatile memory device, the method comprising:
forming a nanowire transistor comprising a nanowire channel; and
forming a resistive memory cell adjacent to the nanowire transistor and in alignment with a longitudinal axis of the nanowire channel.
